(19) United States
(12) Patent Application Publication
(10) Pub. No.: US 2026/0190775 A1
(43) Pub. Date: Jul. 2, 2026

(54) Display Device

(71) Applicant: LG Display Co., Ltd., Seoul (KR)

(72) Inventor: Samjong Lee, Seoul (KR)

(21) Appl. No.: 19/223,594

(22) Filed: May 30, 2025

(30) Foreign Application Priority Data
Dec. 31, 2024 (KR) 10-2024-0201885

(51) Int. Cl. H10K 59/80; H10K 59/124; H10K 59/131; H10K 102/00

(52) U.S. Cl. CPC H10K 59/873; H10K 59/124; H10K 59/131; H10K 2102/3026

(57) ABSTRACT

A display device includes a substrate including a display area and a non-display area, wherein the non-display area includes a pad area disposed on one side edge of the display area; an light-emitting layer disposed on the display area of the substrate; an encapsulation layer disposed on the light-emitting layer and extending to the non-display area; and a plurality of pads disposed in the pad area and arranged so as to be spaced apart from each other in a first direction, wherein an encapsulation layer has an opening area defined therein and exposing the plurality of pads in the pad area, wherein the opening area defines the pad area.

### CROSS-REFERENCE TO RELATED APPLICATION

This application claims priority from Republic of Korea Patent Application No. 10-2024-0201885 filed on Dec. 31, 2024, which is hereby incorporated by reference in its entirety.

### BACKGROUND

### Field

The present disclosure relates to a display device.

### Description of Related Art

An organic light-emitting display device is of a self-emission type, and has an excellent viewing angle, contrast ratio, etc. compared to a liquid crystal display device. The organic light-emitting display device does not require a separate backlight, thereby enabling a lightweight and thin structure, and is advantageous in terms of power consumption. In addition, the organic light-emitting display device has advantages in that it may operate at a low direct current voltage, a response speed thereof is fast, and particularly, a manufacturing cost thereof is low.

Recently, a head-mounted display device for realizing Virtual Reality (VR) or Augmented Reality (AR) has been developed.

### SUMMARY

In order to improve the stereoscopic effect, realism, and immersion of an image displayed from a head-mounted display device, the head-mounted display device requires a display panel for displaying a high-resolution image.

In order to implement a high-resolution display panel, a display panel having a new structure in which an organic light-emitting element is formed on a silicon substrate has been developed.

In addition, a pad opening process of forming an encapsulation layer for protecting the organic light-emitting element over an entirety of the display panel and then removing a portion of the encapsulation layer covering pads using a laser has been developed.

Due to the characteristics of a laser apparatus used in the pad opening process for removing the portion of the encapsulation layer on the pads, there are an initial acceleration zone and a terminal deceleration section. In the initial acceleration zone and the terminal deceleration section the laser irradiation is non-uniform, so that signal lines positioned outwardly of the pads are exposed and damaged.

A purpose of the present disclosure is to provide a display device capable of preventing exposure and damage to lines when removing a portion of an encapsulation layer on pads using a laser.

Purposes according to the present disclosure are not limited to the above-mentioned purpose. Other purposes and advantages according to the present disclosure that are not mentioned may be understood based on following description and may be more clearly understood based on embodiments according to the present disclosure. Further, it will be easily understood that the purposes and advantages according to the present disclosure may be realized using means shown in the claims or combinations thereof.

A display device according to one embodiment of the present disclosure include a substrate including a display area and a non-display area, wherein the non-display area includes a pad area disposed on one side of the display area; an light-emitting layer disposed on the display area of the substrate; an encapsulation layer disposed on the light-emitting layer and extending to the non-display area; and a plurality of pads disposed in the pad area and arranged so as to be spaced apart from each other in a first direction, wherein an encapsulation layer has an opening area defined therein and exposing the plurality of pads in the pad area, wherein the opening area defines the pad area.

In one embodiment, a margin area may be defined between an outer edge of an outermost pad in the first direction among the plurality of pads and an edge of the pad area, wherein signal lines are not disposed in the margin area.

In one embodiment, a width in the first direction of the margin area is in a range of 500 μm or greater.

According to embodiments of the present disclosure, the signal lines are not disposed in the margin area as the area between the outer edge of the outermost pad and the edge of the pad area, and the width of the margin area is 500 μm or greater, thereby preventing exposure of the signal lines to the laser and thus damage thereto in the pad opening process for removing the portion of the encapsulation layer on the pads.

According to embodiments of the present disclosure, the portion of each of the plurality of insulating layers disposed in the margin area MA include the plurality of patterns having the plurality of concave portions or the plurality of convex portions, thereby preventing exposure of the signal lines to the laser and thus damage thereto in the pad opening process for removing the portion of the encapsulation layer on the pads.

According to embodiments of the present disclosure, the defect rate of the display device due to exposure and damage of signal wires in the pad opening process is reduced, so that production energy required for manufacturing the display device may be reduced and greenhouse gas emission for the production may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a plan view schematically illustrating a display device according to an embodiment of the present disclosure.

FIG. 2 is a plan view schematically illustrating a display panel according to an embodiment of the present disclosure.

FIG. 3 is a cross-sectional view taken along a line III-III of FIG. 2 according to an embodiment of the present disclosure.

FIG. 4 is a cross-sectional view taken along a line IV-IV of FIG. 2 according to an embodiment of the present disclosure.

FIGS. 5 to 7 are cross-sectional views schematically illustrating display panels according to embodiments of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, components and/or portions thereof, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or sections, these elements, components, areas, layers and/or sections should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description zone. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’or ‘directly transferred’is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. In this regard, a scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, various embodiments of the present disclosure will be described in detail with reference to the accompanying drawings.

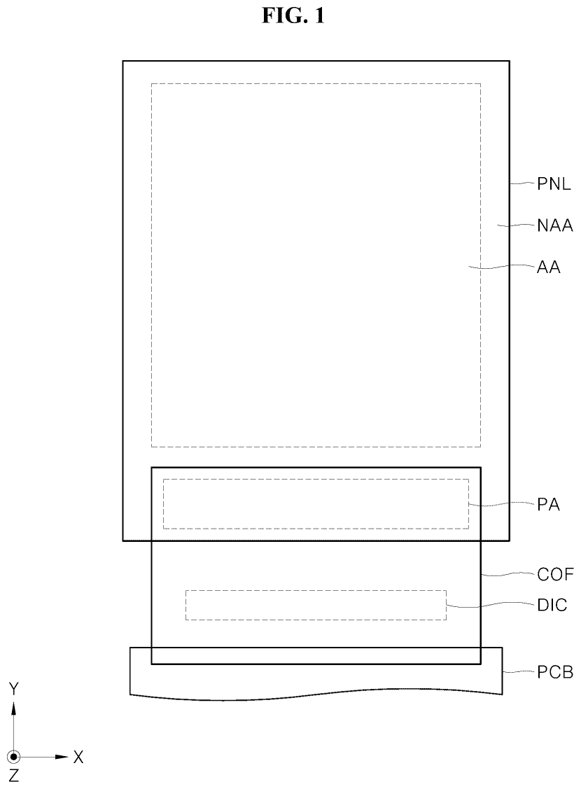

FIG. 1 is a plan view schematically illustrating a display device according to an embodiment of the present disclosure;

Referring to FIG. 1, the display device according to an embodiment of the present disclosure may include a display panel PNL, a chip-on film COF, and a printed circuit board PCB.

The display panel PNL includes a display area AA and a non-display area NAA. The display area AA and the non-display area NAA may be areas of a substrate included in the display panel PNL. The display area AA is an area in which an image is displayed. The non-display area NAA is an area which is positioned outwardly of the display area AA and in which an image is not displayed. The non-display area NAA may be disposed to surround the display area AA. A portion of the non-display area NAA located on one side of the display area AA includes a pad area PA in which a plurality of pads are disposed. The pad area PA may be located on the one side of the display area AA. The non-display area NAA may be disposed on an upper side, a lower side, a left side, and a right side of the display area AA. For example, a portion of the non-display area NAA located on the lower side of the display area AA includes a pad area PA in which a plurality of pads are disposed. The pad area PA may be located on the lower side of the display area AA. The chip-on-film COF may be connected to the pad area PA.

A driving chip DIC may be mounted on the chip-on film COF. The printed circuit board PCB may be connected to the chip-on film COF. A timing controller, a power supply, etc. may be mounted on the printed circuit board PCB. The printed circuit board PCB may be a flexible printed circuit board.

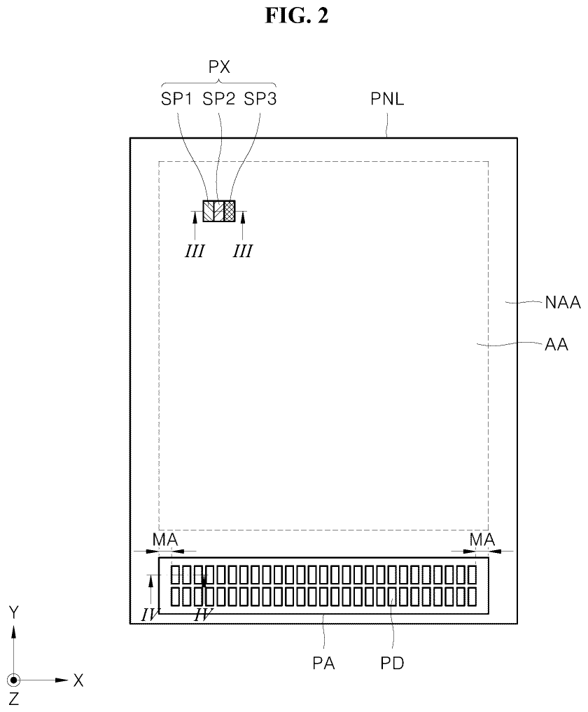

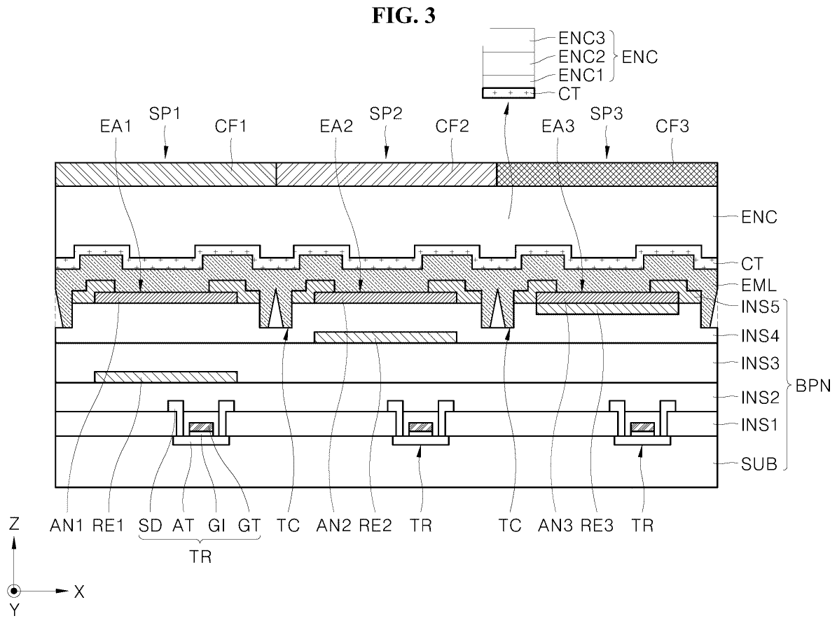

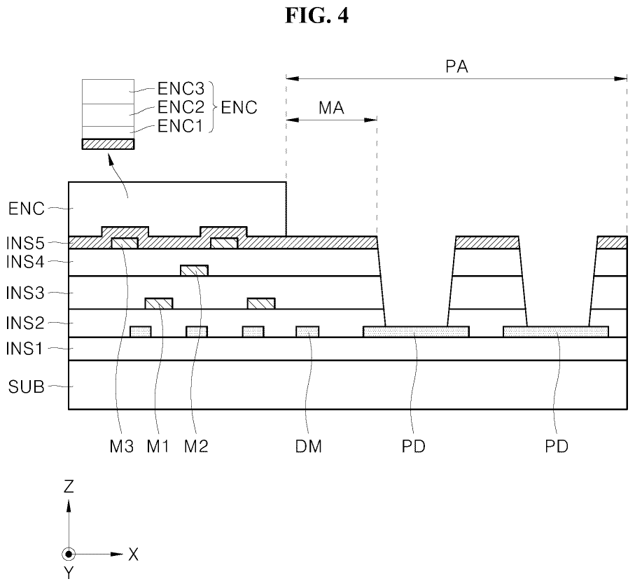

FIG. 2 is a plan view schematically illustrating a display panel according to an embodiment of the present disclosure. FIG. 3 is a cross-sectional view taken along a line III-III of FIG. 2 according to an embodiment of the present disclosure. FIG. 4 is a cross-sectional view taken along a line IV-IV of FIG. 2 according to an embodiment of the present disclosure.

Referring to FIG. 2, the display panel PNL according to an embodiment of the present disclosure may include a plurality of pixels PX disposed in the display area AA. Each pixel PX may include first to third sub-pixels SP1, SP2, and SP3. A gate driver, various lines, and pads PD may be disposed in the non-display area NAA of the display panel PNL. For example, the gate driver may be disposed in the non-display area NAA and in at least one of the left and right sides of the display area AA.

Referring to FIG. 3, the display panel PNL according to an embodiment of the present disclosure may include a backplane substrate BPN, a light-emitting layer EML, a cathode electrode CT, and an encapsulation layer ENC. The backplane substrate BPN may include a substrate SUB, a transistor TR, first to fifth insulating layers INS1, INS2, INS3, INS4, and INS5, first to third reflective electrodes RE1, RE2, and RE3, and first to third anode electrodes AN1, AN2, and AN3.

The display panel according to an embodiment of the present disclosure may operate in a so-called top emission manner in which light emitted from a light-emitting layer is emitted through a cathode electrode.

The substrate SUB may be made of a semiconductor material such as silicon (Si). The substrate SUB may be a semiconductor substrate.

The first sub-pixel SP1, the second sub-pixel SP2, and the third sub-pixel SP3, which are arranged in a first direction, for example, an X direction, are disposed on the substrate SUB. The first sub-pixel SP1 may be a red sub-pixel, the second sub-pixel SP2 may be a green sub-pixel, and the third sub-pixel SP3 may be a blue sub-pixel. The arrangement order and arrangement direction of the first to third sub-pixels SP1, SP2, and SP3 may be variously changed.

A driving circuit including various circuit lines, transistors TR, and a capacitor may be disposed on the substrate SUB on a sub-pixel basis. The circuit lines may include a gate line, a data line, a power line, and a reference line. The transistors TR may include a switching transistor, a driving transistor, and a sensing transistor. For example, the transistors TR may be formed on the substrate SUB using a CMOS process. The transistor TR may include an active layer AT formed on the substrate SUB, a gate insulating film GI and a gate electrode GT sequentially stacked on the active layer AT, and source/drain electrodes SD respectively disposed on both opposing sides of the gate electrode GT and connected to the active layer AT.

The first insulating layer INS1 may be disposed on the substrate SUB. The first insulating layer INS1 may be made of an inorganic insulating material. For example, the first insulating layer INS1 may be made of silicon oxide or silicon nitride.

The first insulating layer INS1 may cover the gate electrode GT of the transistors TR disposed on the substrate SUB. The source/drain electrodes SD of the transistors TR may be disposed on the first insulating layer INS1 and may be connected to the active layer AT of the transistor TR via respective contact holes extending through the first insulating layer INS1.

The second insulating layer INS2 may be disposed on the first insulating layer INS1 and may cover the source/drain electrodes SD of the transistors TR. The second insulating layer INS2 may be made of an inorganic insulating material. For example, the second insulating layer INS2 may be made of silicon oxide.

The first reflective electrode RE1 may be disposed on the second insulating layer INS2. The first reflective electrode RE1 may be disposed in the first sub-pixel SP1. The first reflective electrode RE1 may be made of a metal material having high reflectivity, such as silver (Ag), a silver alloy, aluminum (Al), or an aluminum alloy.

The third insulating layer INS2 may be disposed on the second insulating layer INS2 and the third insulating layer INS3 may cover the first reflective electrode RE1. The third insulating layer INS3 may be made of an inorganic insulating material. For example, the third insulating layer INS3 may be made of silicon oxide.

The second reflective electrode RE2 may be disposed on the third insulating layer INS3. The second reflective electrode RE2 may be disposed in the second sub-pixel SP2. The second reflective electrode RE2 may be made of a metal material having high reflectivity, such as silver (Ag), a silver alloy, aluminum (Al), or an aluminum alloy.

The fourth insulating layer INS4 may be disposed on the third insulating layer INS3, and the fourth insulating layer INS4 may cover the second reflective electrode RE2. The fourth insulating layer INS4 may be made of an inorganic insulating material. For example, the fourth insulating layer INS4 may be made of silicon oxide.

The first anode electrode AN1, the second anode electrode AN2, the third reflective electrode RE3, and the third anode electrode AN3 may be disposed on the fourth insulating layer INS4. The first anode electrode AN1 may be disposed in the first sub-pixel SP1, the second anode electrode AN2 may be disposed in the second sub-pixel SP2, and the third reflective electrode RE3 and the third anode electrode AN3 may be disposed in the third sub-pixel SP3.

In the third sub-pixel SP3, the third reflective electrode RE3 and the third anode electrode AN3 may be in contact with each other.

In an embodiment, instead of the scheme in which the third reflective electrode RE3 and the third anode electrode AN3 contact each other, an additional insulating layer may be further disposed on the third reflective electrode RE3, and the first to third anode electrodes AN1, AN2, and AN3 may be disposed on the additional insulating layer.

The third reflective electrode RE3 may be made of a metal material having high reflectance, such as silver (Ag), a silver alloy, aluminum (Al), or an aluminum alloy. Each of the first to third anode electrodes AN1, AN2, and AN3 may be made of a transparent conductive material such as ITO and IZO capable of transmitting light therethrough.

Each of the first to third anode electrodes AN1, AN2, and AN3 may be electrically connected to the source/drain electrode SD of the transistor TR disposed on the substrate SUB. The first anode electrode AN1 may be electrically connected to the first reflective electrode RE1, and the first reflective electrode RE1 may be electrically connected to the source/drain electrode SD of the transistor TR. The second anode electrode AN2 may be electrically connected to the second reflective electrode RE2, and the second reflective electrode RE2 may be electrically connected to the source/drain electrode SD of the transistor TR.

The fifth insulating layer INS5 may be disposed on the fourth insulating layer INS4. The fifth insulating layer INS5 may cover an edge area of each of the first anode electrodes AN1, AN2, and AN3. A portion of the upper surface of the first anode electrode AN1 which is not covered with the fifth insulating layer INS5 so as to be exposed may be a first light-emission area EA1. A portion of the upper surface of the second anode electrode AN2 which is not covered with the fifth insulating layer INS5 so as to be exposed may be a second light-emission area EA2. A portion of the upper surface of the third anode electrode AN3 not covered with the fifth insulating layer INS5 so as to be exposed may be a third light-emission area EA 3. The fifth insulating layer INS5 may act as a bank or a pixel defining layer.

The fifth insulating layer INS5 may be made of an inorganic insulating material. In an embodiment, the fifth insulating layer INS5 may be made of silicon nitride.

A trench TC having a concave structure may be formed in the fifth insulating layer INS5 and the fourth insulating layer INS4. The trench TC may be positioned in a boundary area between adjacent ones of the sub-pixels SP1, SP2, and SP3 and may extend through the fifth insulating layer INS5 and extend into a predetermined area of the fourth insulating layer INS4. In an embodiment, the trench TC may extend to the third insulating layer INS3 under the fourth insulating layer INS4.

The trench TC allows at least a portion of the light-emitting layer EML to be discontinuous or broken. The at least a portion of the light-emitting layer EML is broken in the trench TC, such that leakage current may be prevented from occurring between adjacent ones of sub-pixels SP1, SP2, and SP3 through the light-emitting layer EML.

The light-emitting layer EML may also be commonly disposed in the first to third sub-pixels SP1, SP2, and SP3. The light-emitting layer EML may be disposed on the first to third anode electrodes AN1, AN2, and AN3 and the fifth insulating layer INS5.

The light-emitting layer EML may be configured to emit, for example, white (W) light. To this end, the light-emitting layer EML may have a tandem structure including a plurality of light emission stacks emitting light of different colors. In an embodiment, the light-emitting layer EML may be configured such that different sub-pixels emit light of different colors. A red light-emitting layer emitting red light may be provided in the first sub-pixel SP1, a green light-emitting layer emitting green light may be provided in the second sub-pixel SP2, and a blue light-emitting layer emitting blue light may be provided in the third sub-pixel SP3.

A cathode electrode CT may be disposed on the light-emitting layer EML. The cathode electrode CT may also be commonly disposed in the first to third sub-pixels SP1, SP2, and SP3.

The cathode electrode CT may be made of a transflective conductive material. The cathode electrode CT may be made of a metal material such as magnesium (Mg), silver (Ag), or an alloy of magnesium (Mg) and silver (Ag). The cathode electrode CT may be formed in the form of a thin film having a thickness of several nm to several tens of nm. Accordingly, as the reflection and re-reflection of light between the cathode electrode CT and the first to third reflective electrodes RE1, RE2, and RE3 may repeatedly occur such that a micro cavity effect may be obtained in the first to third sub-pixels SP1, SP2, and SP3.

According to an embodiment of the present disclosure, a first spacing between the first reflective electrode RE1 and the cathode electrode CT in the first subpixel SP1, a second spacing between the second reflective electrode RE2 and the cathode electrode CT in the second subpixel SP2, and a third spacing between the third reflective electrode RE3 and the cathode electrode CT in the third subpixel SP3 may be different from each other, such that light extraction efficiency and color purity of different colors, for example, red light, green light, and blue light in the first to third subpixels SP1, SP2, and SP3 may be improved due to the micro cavity effect.

The encapsulation layer ENC may be disposed on the cathode electrode CT. The encapsulation layer ENC may be disposed on the light-emitting layer EML to protect the light-emitting layer EML from external moisture. The encapsulation layer ENC may include a plurality of inorganic encapsulation layers stacked on the cathode electrode CT. The encapsulation layer ENC may include, for example, a first encapsulation layer ENC1 made of aluminum oxide, a second encapsulation layer ENC2 made of silicon nitride, and a third encapsulation layer ENC3 made of silicon nitride. The encapsulation layer ENC may extend to the non-display area NAA. The encapsulation layer ENC may be disposed in the remaining area except for the pad area PA of the non-display area NAA.

First to third color filters CF1, CF2, and CF3 may be disposed on the encapsulation layer ENC. The first color filter CF1 vertically overlapping the first light-emission area EA1 may be disposed in the first sub-pixel SP1. The second color filter CF2 vertically overlapping the second light-emission area EA2 may be disposed in the second sub-pixel SP2. The third color filter CF3 vertically overlapping the third light-emission area EA3 may be disposed in the third sub-pixel SP3. The first color filter CF1 may be a red color filter transmitting red light therethrough, the second color filter CF2 may be a green color filter transmitting green light therethrough, and the third color filter CF3 may be a blue color filter transmitting blue light therethrough.

Referring to FIGS. 2 and 4, a plurality of pads PD may be disposed in the pad area PA of the non-display area NAA located on the lower side of the display area AA. The plurality of pads PD may be arranged to be spaced from each other by a predetermined spacing in a first direction, for example, the X-axis direction. The plurality of pads PD may be arranged in, for example, two rows.

The pad area PA of the non-display area NAA may be an area in which the encapsulation layer ENC has been removed to expose the plurality of pads PD. The pad opening process for removing the portion of the encapsulation layer ENC covering the plurality of pads PD in the pad area PA may be performed using a laser. For example, a femtosecond pulse laser having a wavelength of 355 nm may be used in the pad opening process. The encapsulation layer ENC may be removed by repeatedly irradiating laser light to the portion of the encapsulation layer ENC covering the plurality of pads PD during the pad opening process. During the pad opening process, the laser light may be irradiated to the portion of the encapsulation layer ENC while the laser apparatus is moving from a left end of the pad area PA to a right end of the pad area PA in the first direction, for example, the X direction.

A margin area MA may be defined in each of a left edge area and a right edge area of the pad area PA. Each margin area MA may be an area between an outer edge of each of the right and left outermost pads PD among the plurality of pads PD and an edge of the pad area PA. The signal lines are not disposed in the margin area MA. The left and right margin areas MA may be spaced apart from each other in the first direction, for example, the X-axis direction.

Referring to FIG. 4, the first insulating layer INS1 may be disposed on the substrate SUB. A plurality of dummy metal patterns DM and the plurality of pads PD may be disposed on the first insulating layer INS1. The plurality of pads PD may be arranged to be spaced from each other by a predetermined spacing in the first direction, for example, the X-axis direction. The plurality of dummy metal patterns DM may be disposed outwardly of the outermost pad PD to be close to an outer edge of the substrate SUB. For example, the plurality of dummy metal patterns DM and the plurality of pads PD may be made of the same material as that of the source/drain electrode SD of the transistor TR in the display area AA. For example, the first insulating layer INS1 may be made of silicon oxide or silicon nitride.

The second insulating layer INS2 may be disposed on the first insulating layer INS1. The second insulating layer INS2 may cover the plurality of dummy metal patterns DM. The second insulating layer INS2 may include a plurality of openings defined therein exposing the plurality of pads PD. The second insulating layer INS2 may cover the edges of the plurality of pads PD. For example, the second insulating layer INS2 may be made of silicon oxide.

First signal lines M1 may be disposed on the second insulating layer INS2. For example, the first signal lines M1 may be made of the same material as that of the first reflective electrode RE1 of the display area AA. For example, the first signal lines M1 and the first reflective electrode RE1 of the display area AA may be formed simultaneously.

The third insulating layer INS3 may be disposed on the second insulating layer INS2. The third insulating layer INS3 may cover the first signal lines M1. The third insulating layer INS3 may include a plurality of openings defined therein exposing the plurality of pads PD. For example, the third insulating layer INS3 may be made of silicon oxide.

Second signal lines M2 may be disposed on the third insulating layer INS2. For example, the second signal lines M2 may be made of the same material as that of the second reflective electrode RE2 of the display area AA. For example, the second signal lines M2 and the second reflective electrode RE2 of the display area AA may be formed simultaneously.

The fourth insulating layer INS4 may be disposed on the third insulating layer INS3. The fourth insulating layer INS4 may cover the second signal lines M2. The fourth insulating layer INS4 may include a plurality of openings defined therein exposing the plurality of pads PD. For example, the fourth insulating layer INS4 may be made of silicon oxide.

Third signal lines M3 may be disposed on the fourth insulating layer INS4. For example, the third signal lines M3 may be made of the same material as that of the third reflective electrode RE3 of the display area AA. For example, the third signal lines M3 and the third reflective electrode RE3 of the display area AA may be formed simultaneously.

The fifth insulating layer INS5 may be disposed on the fourth insulating layer INS4. The fifth insulating layer INS5 may cover the third signal lines M3. The fifth insulating layer INS5 may include a plurality of openings defined therein exposing the plurality of pads PD. For example, the fifth insulating layer INS5 may be made of silicon nitride.

The openings of the fifth insulating layer INS5, the openings of the fourth insulating layer INS4, the openings of the third insulating layer INS3, and the openings of the second insulating layer INS2 may be positioned to vertically overlap each other. The openings of the fifth insulating layer INS5, the openings of the fourth insulating layer INS4, the openings of the third insulating layer INS3, and the openings of the second insulating layer INS2 may be formed in a single etching process.

The encapsulation layer ENC may be disposed on the fifth insulating layer INS5. A portion of the encapsulation layer ENC may be removed to expose the plurality of pads PD. An opening area of the encapsulation layer ENC exposing the plurality of pads PD may define the pad area PA. The first to third signal lines M1, M2, and M3 are not disposed in the margin area MA of the pad area PA.

Due to characteristics of the laser apparatus used in the pad opening process for removing the portion of the encapsulation layer ENC disposed on the plurality of pads PD, there are an initial acceleration zone and a terminal deceleration zone. In the initial acceleration zone and the terminal deceleration zone of the laser apparatus, the laser irradiation are non-uniform, so that the lines disposed adjacent to the pad area are exposed and damaged. A length of each of the initial acceleration zone and the terminal deceleration zone of the laser apparatus is in a range of about 100 μm to 300 μm.

In order to prevent the first to third signal lines M1, M2, and M3 from being exposed to the laser in the pad opening process, each margin area MA may have a width wider than the initial acceleration zone or the terminal deceleration zone of the laser apparatus. The width of the margin area MA in the first direction, for example, in the X direction, may be 500 μm or greater in consideration of the initial acceleration zone or the terminal deceleration zone of the laser apparatus, the alignment error, etc.

According to an embodiment of the present disclosure, the width of the margin area MA located in each of the left and right edge areas of the pad area PA may be set to be in a range of 500 μm or greater, such that the exposure of the first to third signal lines M1, M2, and M3 to the laser in the pad opening process using the laser may be prevented.

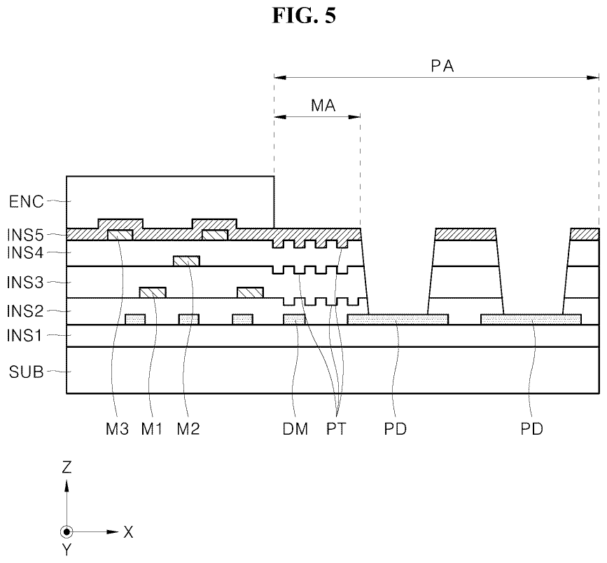

FIGS. 5 to 7 are cross-sectional views schematically illustrating display panels according to embodiments of the present disclosure.

Referring to FIG. 5, in the case of the display panel according to an embodiment of the present disclosure, in the margin area MA of the pad area PA, two or more of the second insulating layer INS2, the third insulating layer INS3, and the fourth insulating layer INS4 may include a plurality of patterns PT including a plurality of concave portions or a plurality of convex portions.

According to an embodiment of the present disclosure, due to the patterns PT of the second insulating layer INS2, the third insulating layer INS3, and the fourth insulating layer INS4, a contact area and an adhesion between the fifth insulating layer INS5 and the fourth insulating layer INS4, a contact area and an adhesion between the fourth insulating layer INS4 and the third insulating layer INS3, and a contact area and an adhesion between the third insulating layer INS3 and the second insulating layer INS2 may be increased.

Accordingly, even though the width of the margin area MA located in each of both opposing edges of the pad area PA is not in the range of 500 μm or greater, the exposure of the first to third signal lines M1, M2, and M3 to the laser may be prevented in the pad opening process using the laser.

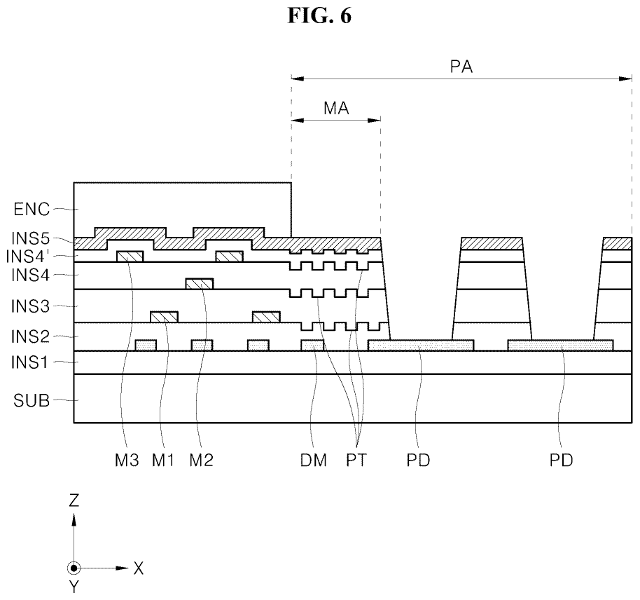

Referring to FIG. 6, a buffer insulating layer INS4′ may be further disposed between the fourth insulating layer INS4 and the fifth insulating layer INS5. The buffer insulating layer INS4′ may cover the third signal lines M3. The buffer insulating layer INS4′ may be made of, for example, silicon oxide. The buffer insulating layer INS4′ may also include a plurality of patterns PT including a plurality of concave portions or a plurality of convex portions in the margin area MA.

The buffer insulating layer INS4′ may include a plurality of openings defined therein exposing the plurality of pads PD.

The openings of the fifth insulating layer INS5, the openings of the buffer insulating layer INS4′, the openings of the fourth insulating layer INS4, the openings of the third insulating layer INS3, and the openings of the second insulating layer INS2 may be positioned to vertically overlap each other. The openings of the fifth insulating layer INS5, the openings of the buffer insulating layer INS4′, the openings of the fourth insulating layer INS4, the openings of the third insulating layer INS3, and the openings of the second insulating layer INS2 may be formed in a single etching process.

According to an embodiment of the present disclosure, due to the patterns PT of the second insulating layer INS2, the third insulating layer INS3, the fourth insulating layer INS4, and the buffer insulating layer INS4′, a contact area and an adhesion between the fifth insulating layer INS5 and the buffer insulating layer INS4′, a contact area and an adhesion between the buffer insulating layer INS4′ and the fourth insulating layer INS4, a contact area and an adhesion between the fourth insulating layer INS4 and the third insulating layer INS3, and a contact area and an adhesion between the third insulating layer INS3 and the second insulating layer INS2 may be increased.

Therefore, even though the width of the margin area MA located in each of both opposing edges of the pad area PA is not in the range of 500 μm or greater, the exposure of the first to third signal lines M1, M2, and M3 to the laser may be prevented in the pad opening process using the laser.

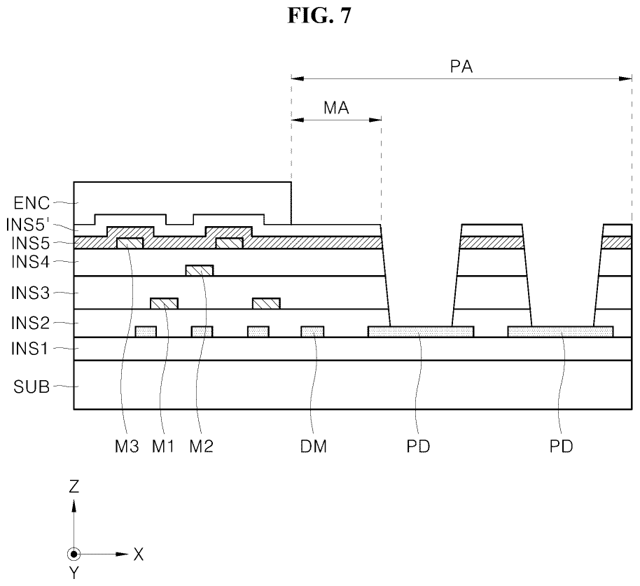

Referring to FIG. 7, the display panel DP according to an embodiment of the present disclosure may further include a protective insulating layer INS5′ disposed on the fifth insulating layer INS5. The protective insulating layer INS5′ may be disposed directly under the encapsulation layer ENC.

The protective insulating layer INS5′ may include a plurality of openings defined therein exposing the plurality of pads PD.

The openings of the protective insulating layer INS5′, the openings of the fifth insulating layer INS5, the openings of the fourth insulating layer INS4, the openings of the third insulating layer INS3, and the openings of the second insulating layer INS2 may be positioned to vertically overlap each other. The openings of the protective insulating layer INS5′, the openings of the fifth insulating layer INS5, the openings of the fourth insulating layer INS4, the openings of the third insulating layer INS3, and the openings of the second insulating layer INS2 may be formed in a single etching process.

The protective insulating layer INS5′ may have a transmittance lower than that of the fifth insulating layer INS5 in relation to the laser light having a wavelength of 355 nm. The protective insulating layer INS5′ may be made of, for example, silicon nitride. The silicon nitride of the protective insulating layer INS5′ may have a different composition from that of the silicon nitride of the fifth insulating layer INS5. The silicon nitride of the protective insulating layer INS5′ may have a higher silicon content than that in the silicon nitride of the fifth insulating layer INS5. Accordingly, the protective insulating layer INS5′ may have a lower transmittance than that of the fifth insulating layer INS5 in relation to the laser light having a wavelength of 355 nm.

According to an embodiment of the present disclosure, the insulating layer having the low transmittance of the laser light is disposed directly under the encapsulation layer, thereby reducing or preventing the insulating layers under the encapsulation layer from being removed by the laser irradiation.

Therefore, even though the width of the margin area MA located in each of both opposing edges of the pad area PA is not in the range of 500 μm or greater, the exposure of the first to third signal lines M1, M2, and M3 to the laser may be prevented in the pad opening process using the laser.

The embodiment of FIG. 7 may be combined with each of the embodiments of FIGS. 4 to 6.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a substrate including a display area and a non-display area, the non-display area including a pad area on one side of the display area;
a light-emitting layer on the display area of the substrate;
an encapsulation layer on the light-emitting layer, the encapsulation layer extending to the non-display area; and
a plurality of pads in the pad area, the plurality of pads spaced apart from each other in a first direction,
wherein an encapsulation layer has an opening area defined therein and exposing the plurality of pads in the pad area,
wherein the opening area defines the pad area.

2. The display device of claim 1, wherein the pad area includes a margin area between an outer edge of an outermost pad in the first direction among the plurality of pads and an outer edge of the pad area,
wherein signal lines are not disposed in the margin area.

3. The display device of claim 2, wherein a width in the first direction of the margin area is in a range of 500 μm or greater.

4. The display device of claim 2, wherein the display device further comprises:
a first insulating layer under the plurality of pads;
a second insulating layer on the first insulating layer without covering the plurality of pads so as to be exposed;
a first signal line on the second insulating layer, the first signal line positioned outwardly of the margin area;
a third insulating layer covering the first signal line and on the second insulating layer without covering the plurality of pads so as to be exposed;
a second signal line on the third insulating layer, the second signal line positioned outwardly of the margin area;
a fourth insulating layer covering the second signal line and on the third insulating layer without covering the plurality of pads so as to be exposed;
a third signal line on the fourth insulating layer, the third signal line positioned outwardly of the margin area; and
a fifth insulating layer covering the third signal line and on the fourth insulating layer without covering the plurality of pads so as to be exposed,
wherein the encapsulation layer is on the fifth insulating layer.

5. The display device of claim 4, wherein each of at least two of the second insulating layer to the fourth insulating layer has a concave-convex pattern in the margin area.

6. The display device of claim further comprising:
a buffer insulating layer covering the third signal line and between the fourth insulating layer and the fifth insulating layer without covering the plurality of pads so as to exposed,
wherein the buffer insulating layer has a concave-convex pattern in the margin area.

7. The display device of claim 6, wherein each of the second insulating layer, the third insulating layer, the fourth insulating layer, and the buffer insulating layer includes silicon oxide.

8. The display device of claim 4, further comprising:
a protective insulating layer on the fifth insulating layer without covering the plurality of pads to be exposed,
wherein the encapsulation layer is on the protective insulating layer.

9. The display device of claim 8, wherein each of the fifth insulating layer and the protective insulating layer includes silicon nitride,
wherein a silicon content in the protective insulating layer is greater than a silicon content in the fifth insulating layer.
